(19) United States
(12) Patent Application Publication
(10) Pub. No.: US 2007/0256637 A1
(43) Pub. Date: Nov. 8, 2007

(54) METHODS AND APPARATUS FOR USING A REINFORCED DIFFUSER IN SUBSTRATE PROCESSING

(75) Inventors: William A. Bagley, Tokyo (JP); Toshio Kiyotake, Kobe (JP); Masahiko Kowaka, Kobe (JP)

Correspondence Address: DUGAN & DUGAN, PC, 55 SOUTH BROADWAY, TARRYTOWN, NY, 10591, US

(73) Assignee: APPLIED MATERIALS, INC.

(21) Appl. No.: 11/741,745

(22) Filed: Apr. 28, 2007

Related U.S. Application Data
(60) Provisional application No. 60/796,298, filed on Apr. 28, 2006.

(51) Int. Cl. C23C 16/00

(52) U.S. Cl. 118/715

(57) ABSTRACT

The invention provides methods and apparatus for using a reinforced gas diffuser in substrate processing. A gas diffuser for use in a PECVD processes includes an aluminum plate with reinforcement material embedded within the aluminum plate. The reinforcement material is adapted to support the aluminum plate and maintain a flatness of the aluminum plate. Numerous other aspects are disclosed.

### CROSS-REFERENCE TO RELATED APPLICATIONS

The present invention claims priority to U.S. Provisional Patent Application Ser. No. 60/796,298 filed on Apr. 28, 2006 and entitled “REINFORCED DIFFUSER FOR SUBSTRATE PROCESSING” (Attorney Docket No. 10202/L) which is incorporated herein by reference in its entirety for all purposes.

### FIELD OF THE INVENTION

The present invention relates to electronic device manufacturing, and more particularly to a reinforced diffuser used in a processing chamber for substrate processing.

### BACKGROUND

Thin film transistors (TFTs) are conventionally made on large glass substrates or plates for use in monitors, flat panel displays, solar cells, personal digital assistants (PDAs), cell phones and the like. TFTs may be made in a cluster tool by sequential deposition of various films including amorphous silicon, doped and undoped silicon oxides, silicon nitride, etc. using Plasma Enhanced Chemical Vapor Deposition (PECVD).

As the sizes of substrates utilized in TFT manufacture continue to be increased (e.g., approaching or exceeding four square meters), achieving the required film uniformity and other necessary or desirable properties may become difficult using conventional tools. Thus, what is needed are improved tools that can consistently provide high quality results such as uniform film thickness and structure.

### SUMMARY

In various aspects of the invention, the present invention provides methods and apparatus for using a reinforced gas diffuser in substrate processing. A gas diffuser for use in a PECVD processes may include an aluminum plate with reinforcement material embedded within the aluminum plate. The reinforcement material is adapted to support the aluminum plate and maintain a flatness of the aluminum plate.

In some aspects, the present invention provides a chamber that includes a chamber wall that encloses a processing region, a vacuum pump coupled to processing region and adapted to evacuate the processing region, a source of processing gas coupled to the processing region and adapted to flow processing gas thereto, and a gas diffuser contained within the processing region and including an aluminum plate with reinforcement material embedded within.

In other aspects, the present invention provides a method of forming a diffuser that includes forming a support structure using a reinforcement material; and embedding the support structure in an aluminum diffuser.

Other features and aspects of the present invention will become more fully apparent from the following detailed description, the appended claims and the accompanying drawings.

### BRIEF DESCRIPTION OF THE DRAWINGS

FIG. 1 is a schematic side view of a plasma enhanced chemical vapor deposition (PECVD) chamber provided in accordance with some embodiments of the present invention.

FIG. 2A is a top perspective view of a conventional diffuser according to the prior art.

FIG. 2B is a top perspective view of the conventional diffuser of FIG. 2A after the diffuser has sagged.

FIG. 3A is a top perspective view of an exemplary diffuser provided in accordance with some embodiments of the present invention.

FIG. 3B is a top plan view of a grid structure that may be used as the reinforcing material for the diffuser of FIG. 3A in some embodiments of the present invention.

FIG. 3C is a top plan view of a honeycomb structure that may be used as the reinforcing material for the diffuser of FIG. 3A in some embodiments of the present invention.

FIG. 3D is an enlarged perspective view of a portion of the honeycomb structure of FIG. 3C in some embodiments of the present invention.

FIG. 4 is a flowchart depicting an example method according to embodiments of the present invention.

### DETAILED DESCRIPTION

The inventors of the present invention have determined that conventional processing chambers may not be able to consistently deposit sufficiently uniform films on substrates because the diffuser plate used in tools is not remaining flat and parallel to the substrates during processing. For example, a non-flat diffuser plate may be unable to be used to form a uniform plasma above a substrate. The inventors of the present invention have determined that the quality of the parts used in the processing chamber becomes critical to achieve required film uniformity and other properties as the size of the substrates being used increases. In particular, the gas diffuser in a PECVD tool is one of the most critical components. Since the diffuser serves as one of the parallel planar electrodes used to generate the plasma, maintaining the flatness of the diffuser is critical to generating a uniform plasma.

The diffuser plate is normally made out of aluminum, although other materials may be used. Aluminum provides both good chemical resistance properties and good electrical conductivity. The aluminum plate is perforated over its entire area for gas injection holes. Since the diffuser is exposed to high temperatures above 200° Celsius in normal operating conditions, the aluminum softens and the center area of the diffuser plate tends to sag or droop down. This sagging negatively affects plasma uniformity which results in deposition film non-uniformity at an unacceptable level. The present invention provides methods and apparatus to prevent the diffuser from sagging through the use of reinforcements installed in the diffuser plate.

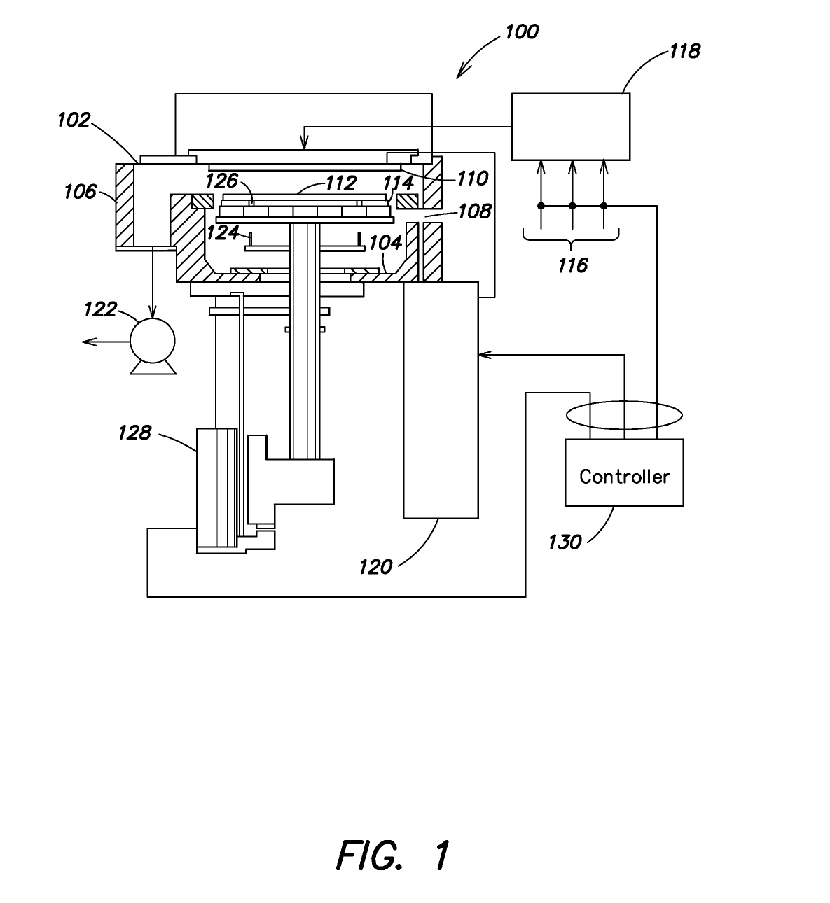

Turning to FIG. 1, a schematic side view of a plasma enhanced chemical vapor deposition (PECVD) chamber 100 is provided in accordance with the present invention. The chamber 100 is a parallel plate CVD chamber having a top 102, a bottom 104, sidewalls 106 and an opening 108 disposed in the sidewall through which substrates are delivered and retrieved from the chamber. Chamber 100 contains a diffuser 110 for dispersing process gases through holes formed through the diffuser to a substrate 112 that rests on a susceptor 114. The diffuser 110 may also be referred to as a diffuser plate, a shower head or plate, a gas distribution manifold or the like. As will be described further below, in accordance with the present invention, the diffuser 110 is “reinforced” so as not to sag following high temperature processing and/or processing cycles.

Deposition and carrier gases are input through gas supply lines 116 into a mixing system 118 where they are combined and then sent to diffuser 110. Alternatively, the mixing system 118 may be omitted and the gases may flow to the diffuser 110 directly. During processing, gases that flow to diffuser 110 are uniformly distributed across the surface of the substrate 112.

In a plasma-enhanced process, a controlled plasma is formed adjacent the substrate 112 by RF energy applied from an RF power supply 120 (e.g., to the diffuser 110, or to another plasma energizing device or structure). The susceptor 114 is grounded and the diffuser 110 is electrically isolated from the other surfaces of the chamber 100. The plasma creates a reaction zone between the diffuser 110 and the substrate 112 that enhances the reaction between the process gases.

A vacuum pump 122 may be coupled to the chamber 100 for maintaining a desired vacuum pressure within the chamber 100 during plasma processing. Additionally, a mechanism for allowing the substrate 112 to be loaded onto and removed from the susceptor 114 may be provided. For example, a plurality of lift pins 124 may be provided that extend through openings 126 in the susceptor 114 so as to raise or lower the substrate 112 relative to the susceptor 114. A motor 128 or similar mechanism may be used to control lift pin/substrate position. A controller 130 may be coupled to the gas supply/mixing system 118, the RF power supply 120 and/or the motor 128 for controlling operation thereof.

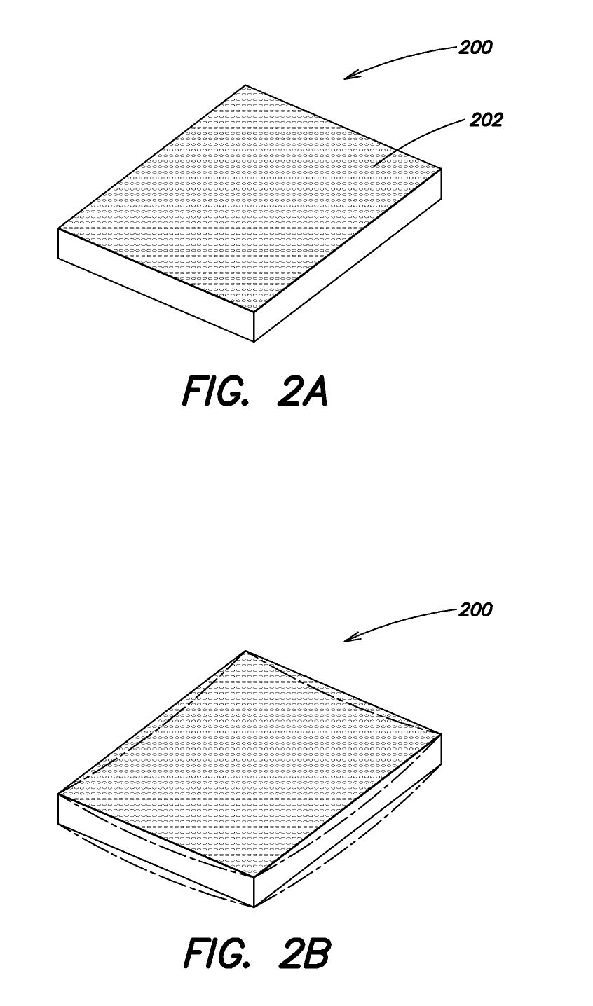

FIG. 2A is a top perspective view of a conventional diffuser 200. The conventional diffuser 200 is typically formed from aluminum due to aluminum's chemical resistance properties and electrical conductivity. The diffuser 200 is perforated with numerous holes 202 that extend through the diffuser and allow the diffuser to uniformly deliver and distribute gas to a processing chamber such as the PECVD chamber 100 of FIG. 1.

Because the conventional diffuser 200 is formed of aluminum, when the diffuser 200 is exposed to high temperature above 200° C. (normal operating conditions for a PECVD chamber), the center area of the diffuser 200 tends to sag as shown in FIG. 2B. Such sagging may require numerous processing cycles to manifest, but nonetheless negatively affects plasma uniformity by altering the spacing between the diffuser 200 and a substrate/susceptor between which a plasma is formed. As a result, deposition film uniformity may be sub-optimal.

The diffuser 200, when employed in a PECVD chamber, is typically not center supported. That is, the edges of the diffuser are supported structurally, but the center must maintain flatness against gravity. A center support may interfere with the uniformity of the plasma and/or the distribution of the gases delivered to the back of the diffuser plate. The strength of aluminum begins to decline rapidly above 150° C. In fact, aluminum begins to soften at 250° C. and exhibits “liquid” type properties at about 660° C. Thus, when exposed to typical PECVD processing temperatures, aluminum diffusers may deflect (e.g., bend or droop). Such deflection is further exacerbated by the current trend toward larger and larger display sizes. As display size increases, so does diffuser size and the probable deflection associated therewith.

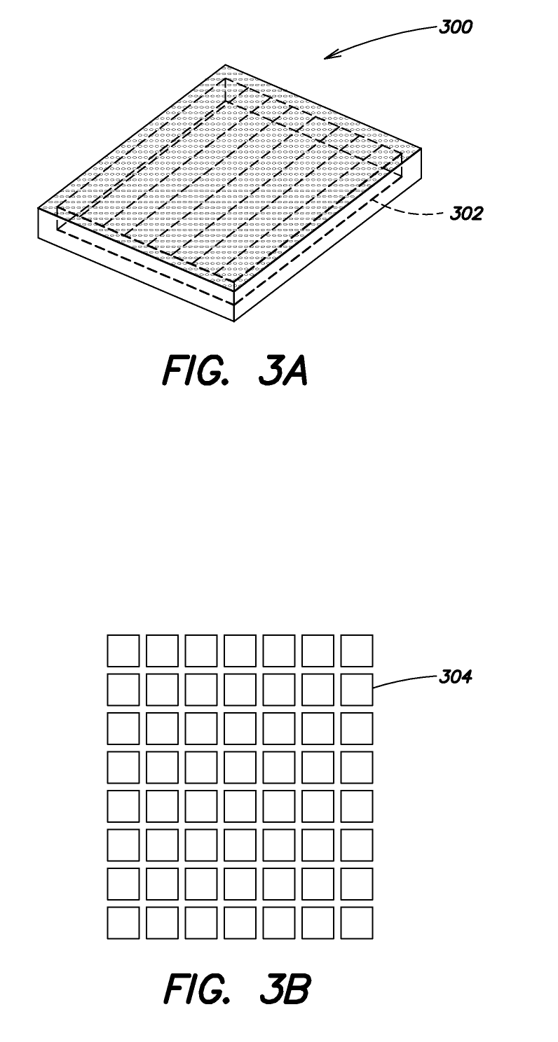

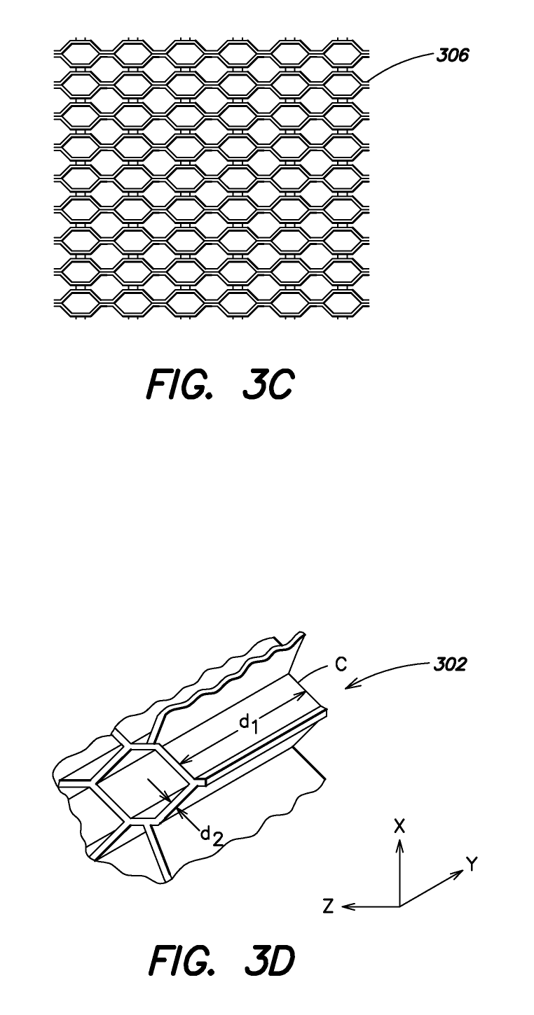

FIG. 3A is a top perspective view of an exemplary diffuser 300 provided in accordance with the present invention. The diffuser 300 is similar to the diffuser 200 of FIG. 2A, but is “reinforced” to prevent the diffuser 300 from sagging following high temperature processing.

In some embodiments, the diffuser 300 may include a reinforcing material or frame 302 embedded within or otherwise included in the diffuser 300. For example, FIG. 3B is a top plan view of a grid structure 304 that may be used as the reinforcing material 302. The grid structure 304 may be formed from bars, plates, bands, beams, I-beams, rods, or the like of reinforcing material, formed from a single piece of material, etc., (as described further below). FIG. 3C is a top plan view of a honeycomb structure 306 that may be used as the reinforcing material 302. Likewise, the honeycomb structure 306 may be formed from bars, plates, bands, beams, I-beams, rods, or the like of reinforcing material, formed from a single piece of material, etc. FIG. 3D is an enlarged perspective view of a portion of the honeycomb structure of FIG. 3C.

In some embodiments, the reinforcement material 302 may be constructed of smaller components which may be either joined to other such components or bent so as to form the grid structure 304, the honeycomb structure 306 or a reinforcement frame having any desired pattern.

As shown in FIG. 3D, the reinforcement material 302 may have a high aspect ratio, with a larger dimension (“d₁”) in a plane in which mechanical strength is desired (e.g., in the plane orthogonal to the substrate 112), than in the perpendicular dimension (“d₂”). For example, the reinforcement material 302 may be formed from components that are tall and thin.

It is contemplated herein to reinforce or otherwise buttress the diffuser 300 against deflection, bending, and/or other deformations. Specifically, the diffuser 300 may be strengthened by adding the reinforcement material 302 or another stiffener such that the diffuser 300 will have a higher strength and be capable of maintain a substantially flat profile in high temperature environments. The inventive diffuser 300 may be formed of aluminum which may be embedded and/or strengthened with a reinforcement material, frame, and/or structure.

Although aluminum is the preferred material for encasing the reinforcement material 302, other “exterior” or encasing materials that are vacuum compatible and that resist corrosion when exposed to chemicals employed during processing (e.g., oxygen, halogens (F, Cl, Br, I, etc.), halogen compounds, atomic form halogens such as fluorine atoms/ions, etc.) may be employed. The reinforcement material 302 is preferably stainless steel or a material that exhibits similar strength at typical processing temperatures (e.g., 300° C. and higher) and is preferably cast within the exterior material as is known in the art. Other exemplary reinforcement materials include nickel or cobalt based alloys (e.g., Iconel®, Haynes®, or Hasteroy® alloys), high strength materials (e.g., steel, titanium, etc.) or compounds (e.g., metal matrix composites, mixtures of aluminum and ceramics, etc.).

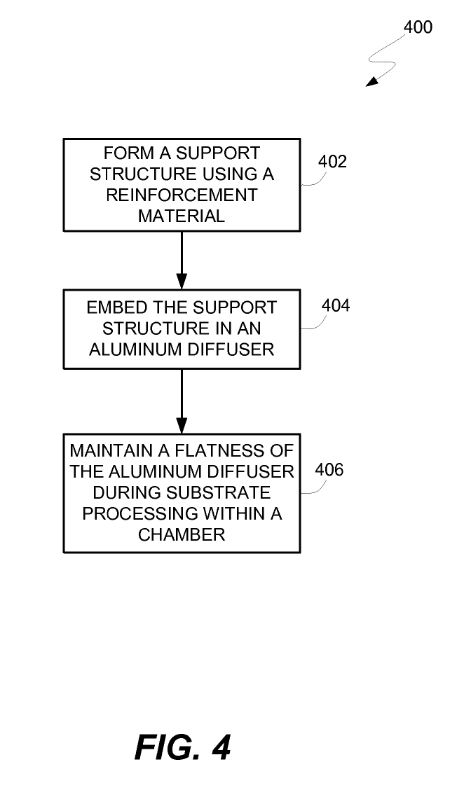

The reinforcement material 302 may take any appropriate structural shape. Exemplary shapes include a grid (as shown in FIG. 3), a bar, a belt, a plate, a band, a beam, an I-beam, a rod, triangles, diamonds, an L-shape, a ladder or H-shape, and a honeycomb (as shown in FIG. 4). In some embodiments, the reinforcement material 302 may be positioned within the inventive diffuser 300 so as to extend along a plane parallel to the substrate 112.

Various construction methods for embedding the reinforcement material within the diffuser may be used. In general, to make the inventive diffuser 300 via casting, the reinforcement material 302 may be placed within a mold that provides the desired shape of the exterior surface. Molten aluminum then may be poured into the mold so as to encase the reinforcement material 302 therewithin. Any other appropriate method for embedding the reinforcement material within the aluminum diffuser plate may be employed.

Turning to FIG. 4, a flowchart depicting an example method 400 according to embodiments of the present invention is provided. In step 402, a support structure as described above is formed from reinforcement material 302. The reinforcement material 302 may take any appropriate structural shape. Exemplary shapes include a grid (as shown in FIG. 3), a bar, a belt, a plate, a band, a beam, an I-beam, a rod, triangles, diamonds, an L-shape, a ladder or H-shape, and a honeycomb (as shown in FIG. 4). In some embodiments, the reinforcement material 302 may be positioned within the inventive diffuser 300 so as to extend along a plane parallel to the substrate 112.

In Step 404, the support structure is embedded in an aluminum diffuser plate. Various construction methods for embedding the reinforcement material within the diffuser may be used. In general, to make the inventive diffuser 300 via casting, the reinforcement material 302 may be placed within a mold that provides the desired shape of the exterior surface. Molten aluminum then may be poured into the mold so as to encase the reinforcement material 302 therewithin. Any other appropriate method for embedding the reinforcement material within the aluminum diffuser plate may be employed.

In some embodiments, the reinforcement material 302 and/or other reinforcement materials may be formed and/or embedded into or otherwise secured to the aluminum diffuser plate 300 via electron beam welding, brazing, or any other appropriate method.

In step 406, the flatness of the diffuser is maintained by the support structure during substrate processing. Thus, even though the aluminum may soften during processing, the support structure made of the reinforcement material holds the diffuser's flatness so that uniform and consistant plasmas may be repeatable and reliably generated.

Inventive diffusers such as those described above can be employed within any high-temperature processing chamber, and are particularly well suited for use in high temperature processes such as the chemical vapor deposition (CVD) of polysilicon.

A diffuser configured in accordance with the present invention may contribute significantly to the value of the processing chamber 100 by enabling substrates to receive more uniform processing. While the above system is exemplary, the invention has application in any arrangement where a diffuser or shower plate is used in a high temperature process, and, thus, it is understood that other applications of the invention are contemplated. While described as horizontally oriented, other diffuser orientations may be employed such as a vertically oriented diffuser or a tilted diffuser that is tilted from a horizontal on a vertical position.

The foregoing description discloses only exemplary embodiments of the invention. Modifications of the above disclosed apparatus and methods which fall within the scope of the invention will be readily apparent to those of ordinary skill in the art. For instance, the inventive diffuser may be used for processing flat panel displays, semiconductor wafers, or the like. It will be understood that the inventive diffuser may be advantageously employed for any high temperature process (e.g., 300° C. and higher). The term “substrate” may include glass panels or plates for flat panel displays, semiconductor substrates, polymer substrates, etc. Other exemplary high temperature processes which may benefit from use of the inventive diffuser include physical vapor deposition, etc. The diffuser may be used for non-plasma applications, such as etch or chemical vapor deposition.

Accordingly, while the present invention has been disclosed in connection with the exemplary embodiments thereof, it should be understood that other embodiments may fall within the spirit and scope of the invention, as defined by the following claims.

What is claimed is:

1. A gas diffuser for use in a PECVD processes comprising:
an aluminum plate with reinforcement material embedded within,
wherein the reinforcement material is adapted to support the aluminum plate and maintain a flatness of the aluminum plate.

2. The gas diffuser of claim 1 wherein the reinforcement material includes stainless steel.

3. The gas diffuser of claim 1 wherein the reinforcement material includes a nickel-based alloy.

4. The gas diffuser of claim 1 wherein the reinforcement material includes a cobalt-based alloy.

5. The gas diffuser of claim 1 wherein the reinforcement material is formed as a honeycomb structure.

6. The gas diffuser of claim 1 wherein the reinforcement material is formed as a bar.

7. The gas diffuser of claim 1 wherein the reinforcement material is formed as a belt.

8. A chamber comprising:
a chamber wall that encloses a processing region;
a vacuum pump coupled to processing region and adapted to evacuate the processing region;
a source of processing gas coupled to the processing region and adapted to flow processing gas thereto; and
a gas diffuser contained within the processing region and including an aluminum plate with reinforcement material embedded within.

9. The chamber of claim 8 wherein the reinforcement material includes stainless steel.

10. The chamber of claim 8 wherein the reinforcement material includes a nickel-based alloy.

11. The chamber of claim 8 wherein the reinforcement material includes a cobalt-based alloy.

12. The chamber of claim 8 wherein the reinforcement material is formed as a honeycomb structure.

13. The chamber of claim 8 wherein the reinforcement material is formed as a bar.

14. The chamber of claim 8 wherein the reinforcement material is formed as a belt.

15. A method of forming a diffuser comprising:
forming a support structure using a reinforcement material; and
embedding the support structure in an aluminum diffuser.

16. The method of claim 15 wherein forming a support structure includes forming a grid using the reinforcement material.

17. The method of claim 15 wherein forming a support structure includes forming a honeycomb using the reinforcement material.

18. The method of claim 15 wherein forming a support structure includes using at least one of stainless steel, a nickel-based alloy, and a cobalt-based alloy as the reinforcement material.

19. The method of claim 15 wherein embedding the support structure includes embedding the support structure by at least one of casting, brazing and electron beam welding.

20. The method of claim 15 further comprising maintaining a flatness of the aluminum plate during substrate processing within a chamber.
